(19) United States
(12) Patent Application Publication
(10) Pub. No.: US 2016/0370621 A1
(43) Pub. Date: Dec. 22, 2016

(54) ARRAY SUBSTRATE, MANUFACTURING METHOD THEREOF AND LIQUID CRYSTAL DISPLAY

(71) Applicant: Shenzhen China Star Optoelectronics Technology Co., Ltd., Shenzhen, Guangdong (CN)

(72) Inventor: Qiuping HUANG, Shenzhen, Guangdong (CN)

(73) Assignee: Shenzhen China Star Optoelectronics Technology Co., Ltd., Shenzhen, Guangdong (CN)

(21) Appl. No.: 14/765,809

(22) PCT Filed: Jun. 30, 2015
(86) PCT No.: PCT/CN2015/082823

§ 371 Date: Aug. 4, 2015

(30) Foreign Application Priority Data
Jun. 18, 2015 (CN) 2015103426195

(51) Int. Cl. G02F 1/1368; H01L 27/12; G02F 1/1343; H01L 29/66; G02F 1/1362; G02F 1/1333; H01L 29/786; H01L 21/02

(52) U.S. Cl. CPC G02F 1/1368; H01L 29/78633; H01L 27/1248; H01L 27/1274; H01L 27/1222; H01L 21/02532; H01L 21/02592; H01L 21/02667; H01L 21/0262; H01L 29/78675; H01L 29/66757; G02F 1/136209; G02F 1/136227; G02F 1/133345; G02F 1/13439

(57) ABSTRACT

The invention relates to an array substrate, a manufacturing method thereof and a liquid crystal display. The array substrate includes a substrate and a light shielding layer, a buffer layer, a semiconductor layer, a gate insulation layer and a gate electrode disposed on the substrate in sequence. A first through-hole is defined on the buffer layer, a second through-hole is defined on the gate insulation layer, and the gate electrode connects to the light shielding layer electrically by the first and the second through-holes. The present invention can improve the capacity of the current drive of the thin-film transistor and enhance the display quality.

### BACKGROUND

### 1. Technical Field

The present invention relates to a liquid crystal display, particularly to an array substrate and a manufacturing method thereof, and a liquid crystal display.

### 2. Description of the Related Art

An organic light-emitting diode (OLED), also named an organic electroluminescence display (OELD), is widely used because of its lightweight, thinness and better power efficiency. The features of OLED take advantage over that of LCD.

At present, OLED technology is frequently used in medium or small sized display panels. The development of semiconductor fabrication technology asks for greater resolution of the display devices, smaller size of corresponding appliances and better performance of thin-film transistors (TFT).

High resolution of the display devices and fast response time of the drive circuits demand TFT devices for triggering switching function immediately. However, the existing current drive capability of semiconductor layers in TFT devices still has room for improvement to match up to the high resolution of the display devices and fast response time of the drive circuit.

### BRIEF SUMMARY

The present invention provides an array substrate,a manufacturing method thereof and a liquid crystal display, being capable of improving the current drive capability of thin-film transistors and achieving better display quality.

To solve the problems above, the present invention provides an array substrate. The array substrate includes a substrate, a light shielding layer, a buffer layer, a semiconductor layer, a gate insulation layer and a gate electrode. The light shielding layer, the buffer layer, the semiconductor layer, the gate insulation layer and the gate electrode are disposed on the substrate in sequence. The light shielding layer includes a first light shielding layer and a second light shielding layer disposing separately. The gate electrode includes a first gate electrode and a second gate electrode. The buffer layer defines a first through-hole corresponding to the first light shielding layer and the second shielding layer. The gate insulation layer defines a second through-hole corresponding to the first gate electrode and the second gate electrode. The first gate electrode connects to the first light shielding layer electrically by the first through-hole and the second through-hole that are connected with each other correspondingly. The second gate electrode connects to the second light shielding layer electrically by the first through-hole and the second through-hole that are connected with each other correspondingly. Wherein the first through-hole and the second through-hole are both formed by photoengraving and etching.

The through-holes are defined in gate terminal or pixel electrode region.

The array substrate also includes an interlamination insulation layer, a source/drain electrode, a passivation layer, an organic insulation layer and a transparent electrode layer disposed on the gate electrode in sequence. A third through-hole is defined on the passivation layer. A fourth though-hole is defined on the organic insulation layer. The transparent electrode layer connects to the source/drain electrode electrically by the third and the fourth through-holes.

To solve the technical problems above, the present invention provides a manufacturing method of the array substrate. The manufacturing method of the array substrate includes: forming a light shielding layer, a buffer layer, a semiconductor layer and a gate insulation layer on the substrate in sequence, forming a first through-hole on the buffer layer and forming a second through-hole on the gate insulation to expose a portion of the light shielding layer; and forming a gate electrode on the gate insulation layer to connect the gate electrode and the light shielding layer by the first through-hole and the second through-hole that connected with each other.

A process of forming the light shielding layer, the buffer layer, the semiconductor layer and the gate insulation layer on the substrate in turn includes: depositing and patterning the light shielding layer on the substrate to form a first light shielding layer and a second light shielding layer; forming the buffer layers on the first light shielding layer and the second light shielding layer; depositing and patterning the semiconductor layer on the buffer layer to form a first semiconductor island corresponding to the first light shielding layer and a second semiconductor island corresponding to the second light shielding layer; and forming the gate insulation layers on the first semiconductor island and the second semiconductor island.

A process of forming the first through-hole on the buffer layer and forming the second through-hole on the gate insulation layer to expose the portion of the light shielding layer is: defining the first through-hole on the buffer layer corresponding to the first light shielding layer and the second light shielding layer, and defining the second through-hole on the gate insulation layer corresponding to the first gate electrode and the second gate electrode, so as to expose portions of the first light shielding layer and the second light shielding layer.

A process of forming the gate electrode on the gate insulation layer to connect the gate electrode and the light shielding layer by the first through-hole and the second through-hole connected with each other is: forming and patterning the gate electrode on the gate insulation layer to form the first gate electrode and the second gate electrode. Wherein the first gate electrode connects to the first light shielding layer electrically by the first and the second through-hole, the second gate electrode connects to the second light shielding layer electrically by the first through-hole and the second through-hole corresponding to the first light shielding layer.

To solve the problems above, the present invention provides a liquid crystal display including a display panel and a backlight source. The display panel includes an array substrate. The array substrate includes a substrate, a light shielding layer, a buffer layer, a semiconductor layer, a gate insulation layer and a gate electrode. The light shielding layer, the buffer layer, the semiconductor layer, the gate insulation layer and the gate electrode disposed on the substrate in sequence. Wherein a first through-hole is defined on the buffer layer, a second through-hole is defined on the gate insulation layer, the gate electrode connects to the light shielding layer electrically by the first through-hole and the second through-hole that connected with each other.

The light shielding layer includes a first light shielding layer and a second light shielding layer disposing separately. The gate electrode includes a first gate electrode and a second gate electrode. The first through-hole defines on the buffer layer corresponding to the first light shielding layer and the second shielding layer. The second through-hole defines on the gate insulation corresponding to the first gate electrode and the second gate electrode. The first gate electrode connects to the first light shielding layer electrically by the first through-hole and the second through-hole that connected with each other correspondingly. The second gate electrode connects to the second light shielding layer electrically by the first through-hole and the second through-hole that connected with each other correspondingly.

The first through-hole and the second through-hole are both formed by photoengraving and etching.

The through-holes are defined in gate terminal or pixel electrode region.

The array substrate also includes an interlamination insulation layer, a source/drain electrode, a passivation layer, an organic insulation layer and a transparent electrode layer arranged on the gate electrode in sequence. A third through-hole is defined on the passivation layer. A fourth though-hole is defined on the organic insulation layer. The transparent electrode layer connects to the source/drain electrode electrically by the third through-hole and the fourth through-hole.

The present invention has advantages as follows. Distinguishing from conventional technique in the present invention,the first through-hole is defined on the buffer layer and the second through-hole is defined on the gate insulation layer, and the gate electrode connects to the light shielding layer electrically by the first and the second through-holes to form a double gate. By this way, the TFT structure of the present invention forms an inversion layer zone between the double gates when charging, which can improve the capacity of the current drive of the thin-film transistor and enhance the display quality.

### BRIEF DESCRIPTION OF THE DRAWINGS

FIG. 1 is a schematic view of an array substrate according to a first exemplary embodiment of the present invention.

FIG. 2 is a first schematic view of an array substrate according to a second exemplary embodiment of the present invention.

FIG. 3 is a second schematic view of an array substrate according to the second exemplary embodiment of the present invention.

FIG. 4 is a flow chart of a manufacturing method of the array substrate according to a first exemplary embodiment of the present invention.

FIG. 5 is a schematic view of through-holes in the manufacture method of the array substrate according to the first exemplary embodiment of the present invention.

FIG. 6 is a flow chart of a manufacturing method of the array substrate according to a second exemplary embodiment of the present invention.

FIG. 7 is a schematic view of a liquid crystal display according to a first exemplary embodiment of the present invention.

### DETAILED DESCRIPTION

Referring to FIG. 1,a schematic view of an array substrate according to a first exemplary embodiment of the present invention, the array substrate includes a substrate 110 and a series of components disposed on the substrate 110 in sequence, which are a light shielding layer 120, a buffer layer 130, a semiconductor layer 140, a gate insulation layer 150 and a gate electrode 160.

A first through-hole 131 is defined on the buffer layer 130. A second through-hole 151 is defined on the gate insulation layer 150.The gate electrode 160 connects electrically to the light shielding layer 120 by the first through-hole 131 and the second through-hole 151.The first through-hole 131 and the second through-hole 151 are connected with each other.

The substrate 110 can be made of glass or plastic, or other transparent materials.

The light shielding layer 120 and the gate electrode 160 can be made of metal, such as copper (Cu), aluminum (Al), molybdenum (Mo), titanium (Ti) or other layered structure.

The buffer layer 130 can besilicon oxide (SiOₓ) or silicon nitride (SiNₓ), which deposits on the semiconductor layer 140 by chemical vapor deposition.

The semiconductor layer 140 forms amorphous silicon on the buffer layer 130 by chemical vapor deposition. The amorphous silicon layer transforms to polycrystalline silicon layer after annealing. Predetermined patterns are formed on the polycrystalline silicon layer by the mask process, and then the semiconductor layer 140 is obtained.

The gate insulation layer 150 can besilicon oxide (SiOₓ) or silicon nitride (SiNₓ) layer, which deposits on the semiconductor layer 140 by chemical vapor deposition.

In the exemplary embodiment, the processes to define the first through-hole 131 on the buffer layer 130 and define the second through-hole 151 on the gate insulation layer 150 can adopt photoengraving or etching, which belong to conventional technique and no more details here.

Different from the conventional technique,the exemplary embodiment forms a double gate by defining the first through-hole on the buffer layer and defining the second through-hole on the gate insulation layer, the gate electrode connects to the light shielding layer electrically by the first and the second through-holes. The first through-hole and the second through-hole are connected. By this way, the TFT structure forms an inversion layer zone between the double gates when charging in order to improve the capacity of the current drive of the thin-film transistor and enhance the display quality.

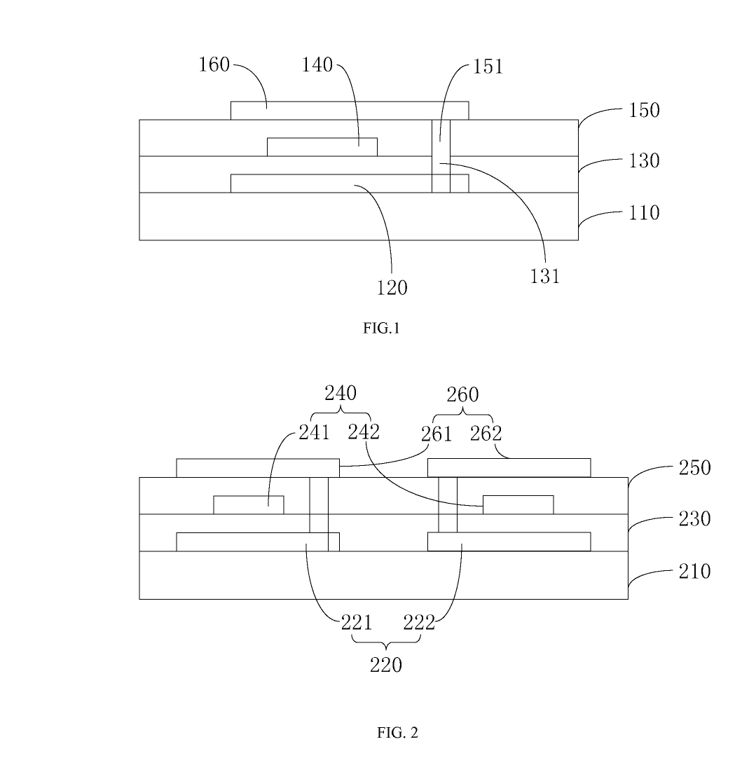

Referring to FIG. 2, a schematic view of an array substrate according to a second exemplary embodiment of the present invention, the array substrate includes the substrate 210 and a series of components disposed on the substrate in sequence—a light shielding layer 220, a buffer layer 230, a semiconductor layer 240, a gate insulation layer 250 and a gate electrode 260. A first through-hole (not shown) is defined on the buffer layer 230. A second through-hole (not shown)is defined on the gate insulation layer 250. The gate electrode 260 connects electrically to the light shielding layer 220 by the first through-hole and the second through-hole.

Specifically, the light shielding layer 220 includes a first light shielding layer 221 and a second light shielding layer 222 that are set separately. The gate electrode 260 includes a first gate electrode 261 and a second gate electrode 262. A first through-hole is defined on the buffer layer 230 corresponding to the first light shielding layer 221 and the second light shielding layer 222 respectively. A second through-hole is defined on the gate insulation layer 250 corresponding to the first gate electrode 261 and the second gate electrode 262respectively. The first gate electrode 261 connects electrically to the first light shielding layer 221 by the first through-hole and the second through-hole that connected with each other correspondingly. The second gate electrode 262 connects electrically to the second light shielding layer 222by the first through-hole and the second through-hole that connected with each other correspondingly.

In other words, the buffer layer 230 has two first through-holes corresponding to the first light shielding layer 221 and the second light shielding layer 222 respectively. The two second through-holes on the gate insulation layer 250 correspond to the first gate electrode 261 and the second gate electrode 262. The first through-hole corresponding to the first light shielding layer 221 and the second through-hole corresponding to the first gate electrode 261 are connected; the first through-hole corresponding to the second light shielding layer 222 and the second through-hole corresponding to the second gate electrode 262 are connected.

In addition, the multi-hole device should keep away from patterned semiconductor layer 240, which is a first semiconductor island 241 and a second semiconductor island 242.

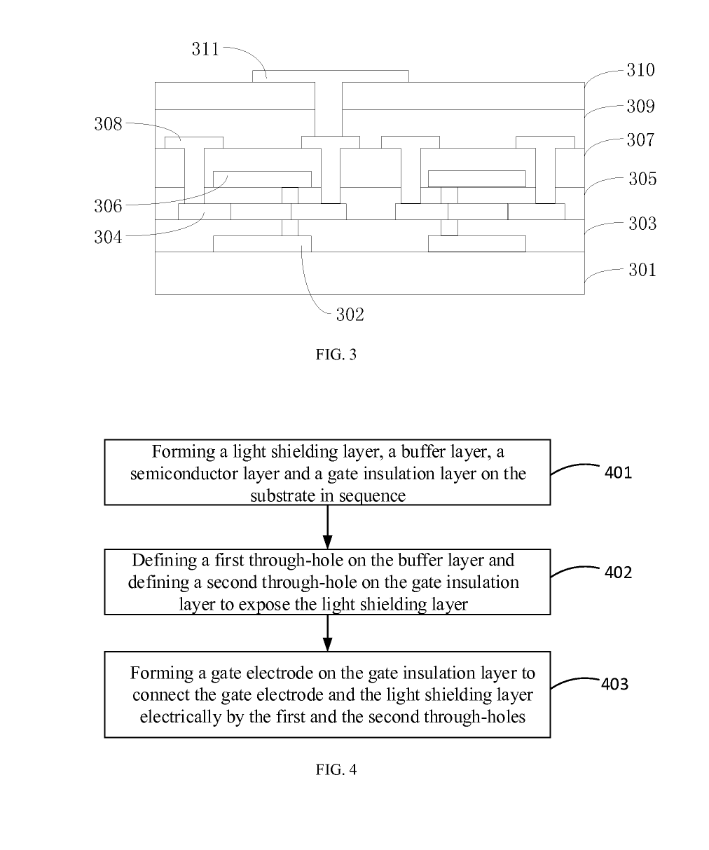

As shown in FIG. 3, in the exemplary embodiment, the array substrate includes a substrate 301 and a series of components disposed on the substrate in sequence, which are a light shielding layer 302, a buffer layer 303, a semiconductor layer 304, a gate insulation layer 305, a gate electrode 306, an interlamination insulation layer 307, a source/drain electrode 308, a passivation layer 309, an organic insulation layer 310 and a transparent electrode layer 311.

A third through-hole is defined on the passivation layer 309 (not shown); a fourth through-hole is defined on the organic insulation layer 310 (not shown). The transparent electrode layer 311 connects electrically to the source/drain electrode 308 by the third through-hole and the fourth through-hole.

The interlamination insulation layer 307 can be silicon oxide (SiOₓ) or silicon nitride (SiN) layer, which deposits on the gate electrode 306 via chemical vapor deposition.

The source/drain electrode 308can be metal, such as copper (Cu), aluminum (Al), molybdenum (Mo), titanium (Ti) or the corresponding layered structures.

The passivation layer 309 is commonly made of inorganic materials or partial inorganic materials.

The organic insulation layer 310 is made of organic materials or partial organic materials, playing the insulation role.

The transparent layer 311 can be indium tin oxide (ITO), or other transparent materials like indium gallium zinc oxide (IGZO).

The transparent electrode layer 311 is anode. An organic light emitting layer is inserted between the anode and the cathode so as to form an electroluminescent diode.

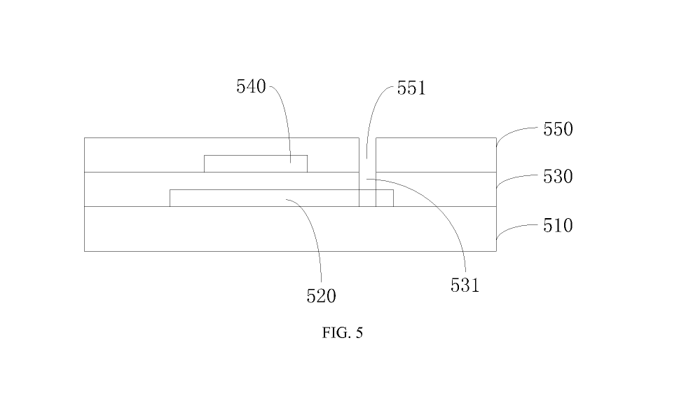

Referring to FIG. 4, a flow chart of a manufacturing method of the array substrate according to the first exemplary embodiment of the present invention. The manufacturing method of the array substrate includes steps as follows.

Step 401: a light shielding layer 520, a buffer layer 530, a semiconductor layer 540 and a gate insulation 550 is formed on a substrate 510 in sequence.

Step 402: a first through-hole 531 is defined on a buffer layer 530 and a second layer 551 is defined on a gate insulation 550 to expose a portion of the light shielding layer 520.

As shown in FIG. 5, a layer of photoresist is coated on the gate insulation layer 550 after formation, then ultraviolet irradiated after heating. The exposure part polymerizes and remains stable in etching solvent; the unexposed part is etched to form the through-holes.

Step 403: a gate electrode (not shown)is formed on the gate insulation layer 550 to connect the gate electrode and the light shielding layer 520 by the first through-hole 531 and second through-hole 551 that connected with each other.

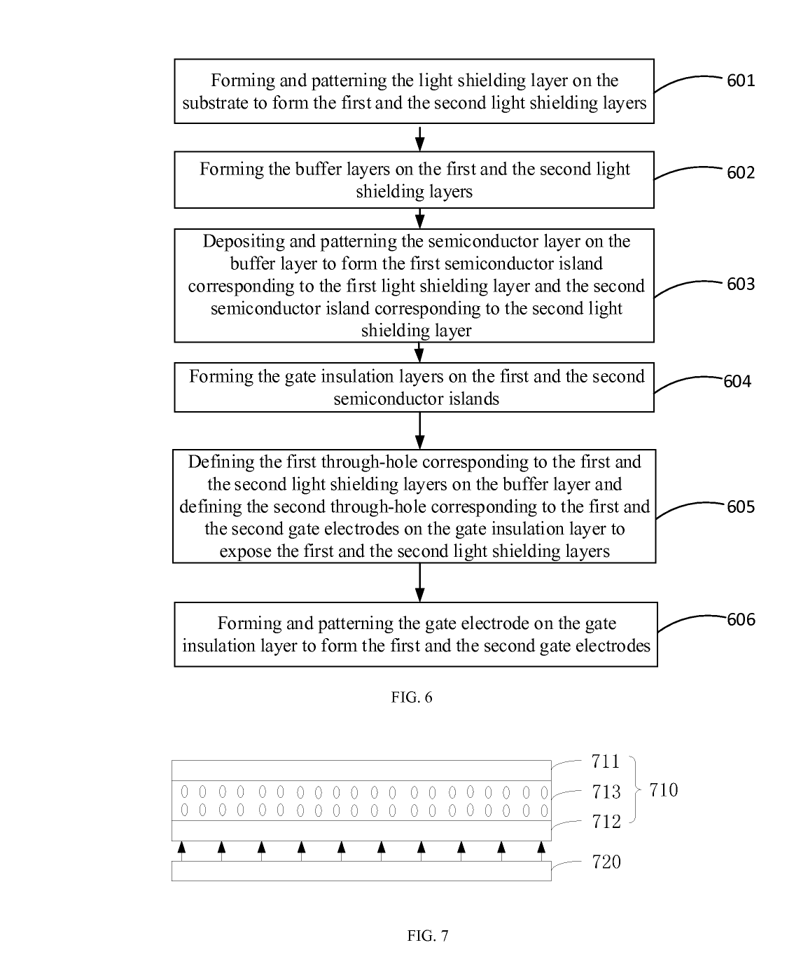

Referring to FIG. 6, a flow chart of a manufacturing method of the array substrate according to the second exemplary embodiment of the present invention. The method includes steps as follows.

Step 601: the light insulation layer is deposited and patterned on the substrate to form the first and the second light shielding layers;

The first and the second light shielding layers are separate and electrical insulation.

Step 602: The buffer layers are formed on the first and the second light shield layers.

The buffer layer can be formed by chemical vapor deposition or physical sputtering.

Step 603: the semiconductor layers are deposited and formed on the buffer layer in order to form the first semiconductor island corresponding to the first light shielding layer and the second semiconductor island corresponding to the second light shielding layer;

In one exemplary embodiment, the first semiconductor island is a NPN-type semiconductor, the second semiconductor island is a PNP-type semiconductor. The first semiconductor is a lightly doped semiconductor. In the other exemplary embodiment, the first semiconductor island can also be a PNP-type semiconductor and the second semiconductor island is a NPN-type semiconductor accordingly.

Step 604: the gate insulation layers are formed on the first and the second semiconductor islands.

Step 605: a first through-hole is defined on the buffer layer corresponding to the first and the second light shielding layers and a second through-hole is defined on the gate insulation layer corresponding to the first and the second gate electrodes to expose the first and the second light shielding layers.

The process is same as described previously and omitted here.

Step 606: the gate electrode is formed and patterned on the gate insulation layer to form the first and the second gate electrodes;

The first gate electrode connects to the first light shielding layer by the first and the second through-holes corresponding to the first light shielding layer; the second gate electrode connects to the second light shielding layer by the first and the second through-holes corresponding to the second light shielding layer.

The patterning processes above can all employ photo engraving and etching and more information is omitted here.

Different from the conventional technique, in the exemplary embodiment, a first through-hole is defined by photoengraving and etching on the gate insulation buffer layer and a second through-hole is defined on the gate insulation layer, the two gate electrodes connect to the counterpart light shielding layers electrically by the first and the second through-holes so as to form a double gate. The first through-hole and the second through-hole are connected. By this way, the TFT structure forms an inversion layer zone between the double gates when charging in order to improve the capacity of the current drive of the thin-film transistor and enhance the display quality.

Referring to FIG. 7, a schematic view of a liquid crystal display according to the first exemplary embodiment of the present invention, the liquid crystal display includes a panel and a backlight source.

A display panel 710 includes a color film substrate 711, an array substrate 712 and a liquid crystal layer 713 between the color film substrate 711 and the array substrate 712; the array substrate 712 is the same substrate as description in above exemplary embodiments and more information is omitted here.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated.

What is claimed is:

1. An array substrate comprising a substrate, a light shielding layer, a buffer layer, a semiconductor layer, a gate insulation layer and a gate electrode; the light shielding layer, the buffer layer, the semiconductor layer, the gate insulation layer and the gate electrode disposed on the substrate in sequence;
the light shielding layer comprising a first light shielding layer and a second light shielding layer disposed separately;
the gate electrode comprising a first gate electrode and a second gate electrode;
a first through-hole defining on the buffer layer corresponding to the first light shielding layer and the second shielding layer, a second through-hole defining on the gate insulation corresponding to the first gate electrode and the second gate electrode; the first gate electrode connecting to the first light shielding layer electrically by the first through-hole and the second through-hole that are connected with each other correspondingly, and the second gate electrode connecting to the second light shielding layer electrically by the first through-hole and the second through-hole that are connected with each other correspondingly;
wherein the first through-hole and the second through-hole are both formed by photoengraving and etching.

2. The array substrate according to claim 1, wherein the through-holes are defined in gate terminal or pixel electrode region.

3. The array substrate according to claim 1, wherein the array substrate also comprises an interlamination insulation layer, a source/drain electrode, a passivation layer, an organic insulation layer and a transparent electrode layer disposed on the gate electrode in sequence;
wherein a third through-hole is defined on the passivation layer, a fourth through-hole is defined on the organic insulation layer, the transparent electrode layer connects to the source/drain electrode by the third and the fourth through-holes.

4. A manufacturing method of the array substrate, wherein the method comprises:
forming a light shielding layer, a buffer layer, a semiconductor layer and a gate insulation layer on the substrate in sequence;
forming a first through-hole on the buffer layer and forming a second through-hole on the gate insulation layer to expose a portion of the light shielding layer; and
forming a gate electrode on the gate insulation layer to connect the gate electrode and the light shielding layer by the first through-hole and the second through-hole that connected with each other.

5. The method according to claim 4, wherein a process of forming the light shielding layer, the buffer layer, the semiconductor layer and the gate insulation layer on the substrate in turn comprises:
depositing and patterning the light shielding layer on the substrate to form a first light shielding layer and a second light shielding layer;
forming the buffer layers on the first light shielding layer and the second light shielding layer;
depositing and patterning the semiconductor layer on the buffer layer to form a first semiconductor island corresponding to the first light shielding layer and a second semiconductor island corresponding to the second light shielding layer; and
forming the gate insulation layers on the first semiconductor island and the second semiconductor island.

6. The method according to claim 5, wherein a process of forming the first through-hole on the buffer layer and forming the second through-hole on the gate insulation layer to expose the portion of the light shielding layer is:
defining the first through-hole on the buffer layer corresponding to the first light shielding layer and the second light shielding layer, and defining the second through-hole on the gate insulation layer corresponding to the first gate electrode and the second gate electrode, so as to expose portions of the first light shielding layer and the second light shielding layer.

7. The method according to claim 6, wherein a process of forming the gate electrode on the gate insulation layer to connect the gate electrode and the light shielding layer by the first through-hole and the second through-hole connected with each other is:
forming and patterning the gate electrode on the gate insulation layer to form the first gate electrode and the second gate electrode;
wherein the first gate electrode connects to the first light shielding layer electrically by the first and the second through-hole, the second gate electrode connects to the second light shielding layer electrically by the first through-hole and the second through-hole corresponding to the first light shielding layer.

8. A liquid crystal display comprising a display panel and a backlight source, wherein the display panel comprises an array substrate;
the array substrate comprising a substrate, a light shielding layer, a buffer layer, a semiconductor layer, a gate insulation layer and a gate electrode; the light shielding layer, the buffer layer, the semiconductor layer, the gate insulation layer and the gate electrode disposed on the substrate in sequence;
wherein a first through-hole is defined on the buffer layer, a second through-hole is defined on the gate insulation layer, the gate electrode connects to the light shielding layer electrically by the first through-hole and the second through-hole that connected with each other.

9. The liquid crystal display according to claim 8, wherein the light shielding layer comprises a first light shielding layer and a second light shielding layer disposed separately;
the gate electrode comprising a first gate electrode and a second gate electrode;
the first through-hole defining on the buffer layer corresponding to the first light shielding layer and the second shielding layer, the second through-hole defining on the gate insulation corresponding to the first gate electrode and the second gate electrode; the first gate electrode connecting to the first light shielding layer electrically by the first through-hole and the second through-hole that connected with each other correspondingly, and the second gate electrode connecting to the second light shielding layer electrically by the first through-hole and the second through-hole that connected with each other correspondingly.

10. The liquid crystal display according to claim 8, wherein the first through-hole and the second through-hole are both formed by photoengraving and etching.

11. The liquid crystal display according to claim 8, wherein the through-holes are defined in gate terminal or pixel electrode region.

12. The liquid crystal display according to claim 8, wherein the array substrate also comprises an interlamination insulation layer, a source/drain electrode, a passivation layer, an organic insulation layer and a transparent electrode layer disposed on the gate electrode in sequence;
wherein a third through-hole is defined on the passivation layer, a fourth through-hole is defined on the organic insulation layer, the transparent electrode layer connects to the source/drain electrode electrically by the third through-hole and the fourth through-hole.
